(19) United States
(12) Patent Application Publication
(10) Pub. No.: US 2026/0262333 A1
(43) Pub. Date: Sep. 3, 2026

(54) SUCTION CUP DEVICE AND METHOD FOR REMOVING SAPPHIRE SUBSTRATE

(71) Applicant: Lumileds LLC, San Jose, CA (US)

(72) Inventors: Joyce Chan Li Kin, Singapore (SG); Chee Chung James Wong, Singapore (SG); Yeow Meng Teo, Singapore (SG)

(73) Assignee: Lumileds LLC, San Jose, CA (US)

(21) Appl. No.: 18/994,783

(22) PCT Filed: Aug. 18, 2023
(86) PCT No.: PCT/US2023/030615

§ 371 Date: Jan. 15, 2025

Related U.S. Application Data
(60) Provisional application No. 63/399,512, filed on Aug. 19, 2022.

(51) Int. Cl. H10H 20/01; H10P 72/76; H10P 72/78

(52) U.S. Cl. CPC H10H 20/019; H10P 72/7618; H10P 72/78

(57) ABSTRACT

A light emitting diode (LED) device sapphire substrate removal apparatus and method are disclosed. The apparatus and method includes placing the LED device comprising a sapphire substrate and a carrier onto holding stage sized and shaped to hold the carrier of an LED device and applying suction cups to the sapphire substrate to separate the sapphire substrate from the carrier. The apparatus include the holding stage and a sapphire substrate suction device.

### TECHNICAL FIELD

Embodiments of the disclosure generally relate to light emitting devices, and in particular, post laser lift-off of materials and structures for removing layers, such as sapphire substrates, from light emitting diode (LED) devices during the manufacture of LEDs.

### BACKGROUND

Layers are commonly grown on a carrier or a substrate, such as a sapphire substrate, to form LEDs. A few examples of epitaxial (EPI) layer materials include gallium nitride (GaN), aluminum gallium nitride (AlGaN), aluminum nitride (AlN), indium nitride (InN) and indium gallium nitride (InGaN). In this disclosure, a GaN layer will be used as a non-limiting example for an exemplary description of a laser lift-off (LLO) process.

As shown in FIG. 1, a prior art laser lift-off process 100 is used to separate a substrate, such as a sapphire substrate 104, from a GaN interface 106 of an LED device 101 using a laser source 102. The sapphire substrate 104 is on the GaN interface 106, which is on an interconnect 108, which is mounted on a carrier 110 (which can also be referred to as a sub-mount or sub-mount tile), such that the interconnect 108 is disposed between the GaN interface 106 and the carrier 110. This technique has been used to increase the luminous efficiency of GaN-based LEDs. The sapphire substrate 104, the GaN interface 106, and the interconnect 108 are bonded onto the carrier 110 by an underfill adhesive disposed between the interconnect 108 and the carrier 110. Conventional laser lift-off methods used in LED manufacturing processes use a single shot laser beam. The laser source 102 generates a laser beam that is directed towards and passes through the sapphire substrate 104 and is absorbed by the GaN interface 106 at high temperatures. Thermal decomposition of the GaN interface 106 occurs when high energy from the laser source 102 induces local heating on the GaN interface 106 above the critical sublimation temperature of gallium (Ga), forming metallic Ga and gaseous nitrogen (N₂) as shown in the equation: 2GaN(s)→2Ga(l)+N₂(g). Removal of the sapphire substrate 104 occurs via the instantaneous N₂ vaporization pressure generated, which lifts the sapphire substrate 104 from the GaN interface 106.

A challenge in sapphire substrate removal is that sapphire can be melted onto the GaN interface layer during the laser lift-off process. In some instances, the sapphire substrate melts and forms one or more forms of alumina (aluminum oxide), for example, crystalline alumina such as alpha alumina or polycrystalline alumina or amorphous alumina. These different forms of alumina form at high temperature due to partial transmission and reflection amplitudes when the laser moves from a low (sapphire) to high (GaN) refractive index medium, causing rapid cooling. When rapid cooling occurs, the alumina will stick to the GaN and sapphire surfaces. This may cause the sapphire substrate to remain intact and prevent the laser lift-off from removing the sapphire substrate from the GaN interface.

There is a need to address the challenges of sapphire substrate removal after a laser lift-off process in which the sapphire substrate remains adhered to the GaN interface.

### SUMMARY

An aspect of the disclosure pertains to a light emitting diode (LED) device sapphire substrate removal apparatus comprising a holding stage sized and shaped to hold a carrier of an LED device including a sapphire substrate; and a suction device positioned to apply a suction force to the sapphire substrate to remove the sapphire substrate from the LED device.

Embodiments according to this aspect can include one or more of the following features. The holding stage comprises a suction system configured to apply suction to the LED device sufficient to hold the LED device to the holding stage during a sapphire substrate removal operation. The holding stage and the suction device are movable with respect to each other in a vertical direction. The LED device sapphire substrate removal apparatus further comprises a first motor and a shaft configured to move the suction device in the vertical direction. The LED device sapphire substrate removal apparatus further comprises a second motor and a second shaft configured to move the holding stage in the vertical direction. The suction device comprises a first plurality of suction cups. The holding stage comprises a second plurality of suction cups. The LED device sapphire substrate removal apparatus further comprises a first vacuum pump in fluid communication with at least one of the suction device and the holding stage. The LED device sapphire substrate removal apparatus further comprises a second vacuum pump in fluid communication with the holding stage. The first vacuum pump is in fluid communication with the suction device and the holding stage, and the first vacuum pump is configured to provide a holding force on the carrier of the LED device and a pulling force on the sapphire substrate sufficient to remove the sapphire substrate from the LED device when the holding stage and the suction device are moved apart. The second vacuum pump is configured to provide a holding force on the carrier of the LED device, and the first vacuum pump is configured to provide a pulling force on the sapphire substrate sufficient to remove the sapphire substrate from the LED device when the holding stage and the suction device are moved apart. The LED device sapphire substrate removal apparatus further comprises a controller configured to control operation of at least one of the first vacuum pump and the second vacuum pump. The holding stage is mounted to a pedestal configured to move the holding stage in a vertical direction.

Another aspect of the disclosure pertains to a method of removing a sapphire substrate from an LED device, the method comprising: placing the LED device comprising the sapphire substrate and a carrier onto a holding stage, the holding stage sized and shaped to hold the carrier of the LED device; applying a suction device to the sapphire substrate; and separating the suction device and the holding stage to separate the sapphire substrate from the carrier, wherein after separation of the sapphire substrate from the carrier the carrier of the LED device is held on the holding device and the sapphire substrate is held on the suction device.

Embodiments according to this aspect can include one or more of the following features. The method further comprises prior to applying the suction device to the sapphire substrate, aligning the suction device with the holding stage such that the LED device is disposed therebetween. At least one of the holding stage and the suction device are movable with respect to each other in a vertical direction, and separating the suction device and the holding stage to separate the sapphire substrate from the carrier comprises moving at least one of the holding stage and the suction device vertically away from each other. Applying the suction device to the sapphire substrate comprises moving the suction device with respect to the holding device until the suction device contacts the sapphire substrate. The method further comprises applying vacuum suction to at least one of (a) the holding stage to apply a holding force to the carrier of the LED device and (b) the suction device to apply a pulling force to the sapphire substrate. The holding force and the pulling force are sufficient to remove the sapphire substrate from the LED device as the holding stage and the suction device are moved apart. The suction device comprises a plurality of suction cups. The holding device comprises a plurality of suction cups.

### BRIEF DESCRIPTION OF THE DRAWINGS

So that the manner in which the above recited features of the present disclosure can be understood in detail, a more particular description of the disclosure, briefly summarized above, may be had by reference to embodiments, some of which are illustrated in the appended drawings. It is to be noted, however, that the appended drawings illustrate only typical embodiments of this disclosure and are therefore not to be considered limiting of its scope, for the disclosure may admit to other equally effective embodiments. The embodiments as described herein are illustrated by way of example and not limitation in the figures of the accompanying drawings in which like references indicate similar elements. The figures herein are not to scale.

FIG. 1 is a schematic view illustrating a prior art laser lift-off process to remove a sapphire substrate from a light emitting diode die;

FIG. 2A is a bottom perspective view of a suction cup device for removing a sapphire substrate from a light emitting diode (LED) device according to one or more embodiments;

FIG. 2B is a perspective view of a suction cup apparatus for removing a sapphire substrate from a light emitting diode (LED) according to one or more embodiments, including the suction cup device shown in FIG. 2A and a holding stage;

FIG. 2C is a side view of the suction cup apparatus for removing a sapphire substrate from a light emitting diode (LED) shown in FIG. 2B, and including first and second motors and shafts in connection with the suction cup device and holding stage;

FIG. 3A is a side view of the suction cup apparatus for removing a sapphire substrate from a light emitting diode (LED) shown in FIG. 2B;

FIG. 3B is a side view of the suction cup apparatus for removing a sapphire substrate from a light emitting diode (LED) shown in FIG. 3A in use with the suction cup device lowered to engage the sapphire substrate of the light emitting diode (LED) device positioned on the holding stage;

FIG. 3C is a side view of the suction cup apparatus for removing a sapphire substrate from a light emitting diode (LED) shown in FIG. 3A in use, with portions of the apparatus exposed to show engagement of the suction cup device with the sapphire substrate;

FIG. 3D is a side view of the suction cup apparatus for removing a sapphire substrate from a light emitting diode (LED) shown in FIG. 3A in use, after the suction cup device has been lifted with the removed sapphire substrate attached;

FIG. 4 is a flow chart illustrating a method according to one or more embodiments; and

FIG. 5 is a perspective view illustrating removal of a sapphire substrate from an LED die including a trenched metal grid.

### DETAILED DESCRIPTION

Before describing several exemplary embodiments of the disclosure, it is to be understood that the disclosure is not limited to the details of construction or process steps set forth in the following description. The descriptions in the disclosure are capable of other embodiments and of being practiced or being carried out in various ways.

Reference to an LED (or the plural, LEDs) refers to a light emitting diode device at the wafer or the die level that emits light when current flows through the LED. In one or more embodiments, the LEDs herein have one or more characteristic dimensions (e.g., height, width, depth, thickness, etc. dimensions). In one or more embodiments, the length and the width are in a range from about 1 mm to about 350 mm. In one or more embodiments, one or more dimensions of height, width, depth, and thickness have values in a range of from about 1 mm to about 300 mm, from about 1 mm to about 150 mm, or from about 1 mm to about 100 mm. LED devices according to some embodiments include micro-LEDs (uLEDs or uLEDs), referring to a light emitting diode having one or more characteristic dimensions (e.g., height, width, depth, thickness, etc. dimensions) of less than 100 micrometers. In one or more embodiments, one or more dimensions of height, width, depth, and thickness of an LED die have values in a range of from about 1 mm to about 300 mm, for example, from about 1 mm to about 75 mm, for example from about 1 mm to about 50 mm, from about 1 mm to about 25 mm, from about 2 mm to about 25 mm, or from about 3 mm to about 15 mm. Overall, in one or more embodiments, the LEDs herein may have a characteristic length and width dimension ranging from about 1 mm to about 350 mm, and all values and sub-ranges therebetween. The thickness dimension of various semiconductor layers and the sapphire substrate may be expressed in micrometers. For example, in some embodiments, the semiconductor layers (such as the GaN interface 106) discussed herein have a thickness in a range of from about 2 μm to about 50 μm, for example from about 2 μm to about 30 μm, or about 2 μm to about 20 μm. In some embodiments, the thickness of the sapphire substrate 104 is in a range of from about 100 μm to about 800 μm.

LEDs capable of operation across the visible spectrum include Group III-V semiconductors, particularly binary, ternary, and quaternary alloys of gallium, aluminum, indium, and nitrogen, also referred to as III-nitride materials. Typically, III-nitride light emitting devices are fabricated by epitaxially growing a stack of semiconductor layers of different compositions and dopant concentrations on a growth substrate such as a sapphire, silicon carbide, III-nitride, or other suitable substrate by metal-organic chemical vapor deposition (MOCVD), molecular beam epitaxy (MBE), or other epitaxial techniques. Sapphire is often used as the growth substrate due to its wide commercial availability and relative ease of use. The stack grown on the growth substrate typically includes one or more n-type layers doped with, for example, Si, formed over the substrate, a light emitting or active region formed over the n-type layer or layers, and one or more p-type layers doped with, for example, Mg, formed over the active region. An LED die is a structure including a substrate and the stack of semiconductor layers

Methods of depositing materials, layers, and thin films to form LEDs include but are not limited to: sputter deposition, atomic layer deposition (ALD), chemical vapor deposition (CVD), physical vapor deposition (PVD), plasma enhanced atomic layer deposition (PEALD), plasma enhanced chemical vapor deposition (PECVD), and combinations thereof.

Methods of forming or growing semiconductor layers including n-type layers, active regions, and p-type layers can be in accordance with methods known in the art. In one or more embodiments, the semiconductor layers are formed by epitaxial (EPI) growth. The semiconductor layers according to one or more embodiments comprise epitaxial layers, III-nitride layers, or epitaxial III-nitride layers. In one or more embodiments, the semiconductor layers comprise a III-nitride material, and in specific embodiments, an epitaxial III-nitride material. In some embodiments, the III-nitride material comprises one or more of gallium (Ga), aluminum (Al), and indium (In). Thus, in some embodiments, the semiconductor layers comprise one or more of gallium nitride (GaN), aluminum nitride (AlN), indium nitride (InN), aluminum gallium nitride (AlGaN), indium gallium nitride (InGaN), indium aluminum nitride (InAlN), aluminum indium gallium nitride (AlInGaN), and the like. The III-nitride materials may be doped with one or more of silicon (Si), oxygen (O), boron (B), phosphorus (P), germanium (Ge), manganese (Mn), or magnesium (Mg) depending upon whether p-type or n-type III-nitride material is needed. In one or more embodiments, the semiconductor layers have a combined thickness in a range of from about 2 μm to about 10 μm, and all values and subranges therebetween.

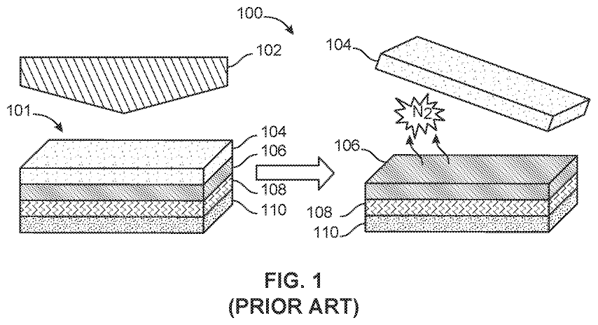

Thus, according to one or more embodiments, in the manufacture of an LED, a GaN interface is formed on a sapphire substrate, followed by one or more n-type layers, one or more active layers, and one or more p-type layers that form the interconnect 108 (e.g., as shown in FIG. 1). Metallic conductors may be formed through and upon one or more of the layers to provide coupling of the n-type and p-type layers to an external source of power to activate the active layer(s) of the light emitting element, via contact pads above the uppermost (p-type) layer.

As discussed above, laser lift-off is a process that is commonly used to remove the sapphire substrate from an LED device. A laser pulse is projected toward and through the sapphire substrate and is absorbed by the semiconductor layer at the sapphire-semiconductor interface, causing thermal decomposition of the semiconductor layer at the interface. The laser pulse in some embodiments comprises multiple pulsed laser shots that are stitched together (e.g., by raster scanning multiple smaller laser beams) to cover an entire area of a sapphire substrate that is removed at the wafer level or from a die comprising multiple LEDs. In other embodiments, the laser pulse is a single shot laser that covers the entire area of a sapphire substrate that is removed at the water level or from a die comprising multiple LEDs. In a specific embodiment, a single shot laser is used, comprising an ArF excimer laser with a flat top beam having a beam size in a range from 1 mm×1 mm to 2.2 mm×2.7 mm, which is useful for dies up to 2.2 mm×2.7 mm (width×length). In another specific embodiment, a KrF excimer laser is used for laser lift-off of a micro-LED, using a flat top laser beam having a beam size in a range from 200 micrometers×200 micrometers to 500 micrometers×500 micrometers. By using beam stitching, laser lift-off can be performed on micro-LED die sizes greater than 2.2 mm×2.7 mm (width×length) and as defined herein for micro-LEDs. In another specific embodiment, wafer level laser lift-off is performed using a KrF excimer laser having a flat top beam having a beam size in a range from 200 micrometers×200 micrometers to 500 micrometers×500 micrometers. By using beam stitching, laser lift-off can be performed at the wafer level. As discussed above, when the laser lift-off procedure does not succeed in removing the sapphire substrate from the GaN interface, the sapphire substrate is adhered to the GaN interface and, unless it is removed, the wafer or die will have to be discarded, resulting in a loss of process yields, valuable material, and manufacturing time. Thus, one or more embodiments described herein solves an important problem by providing apparatus and methods to complete lift-off or removal of the sapphire substrate when the laser lift-off process has not resulted in removal of the sapphire substrate from the GaN interface, solving an expensive and difficult problem.

In one or more embodiments, in which the laser lift-off and the subsequent sapphire removal described by the method and apparatus described in this disclosure are performed at the wafer level, the wafer-size sapphire substrate is removed after the whole wafer has been processed. In other embodiments, in which the laser lift-off and the subsequent sapphire substrate removal described by the method and apparatus described in this disclosure are performed for each individual die, the dies are flip-chip mounted on the carrier 110 (or sub-mount)(e.g., as shown in FIG. 1), with the sapphire substrate facing upward. The laser is applied to each die, and the die-size sapphire chips are removed after the laser is incident on each die, leaving the semiconductor structure on the carrier 110.

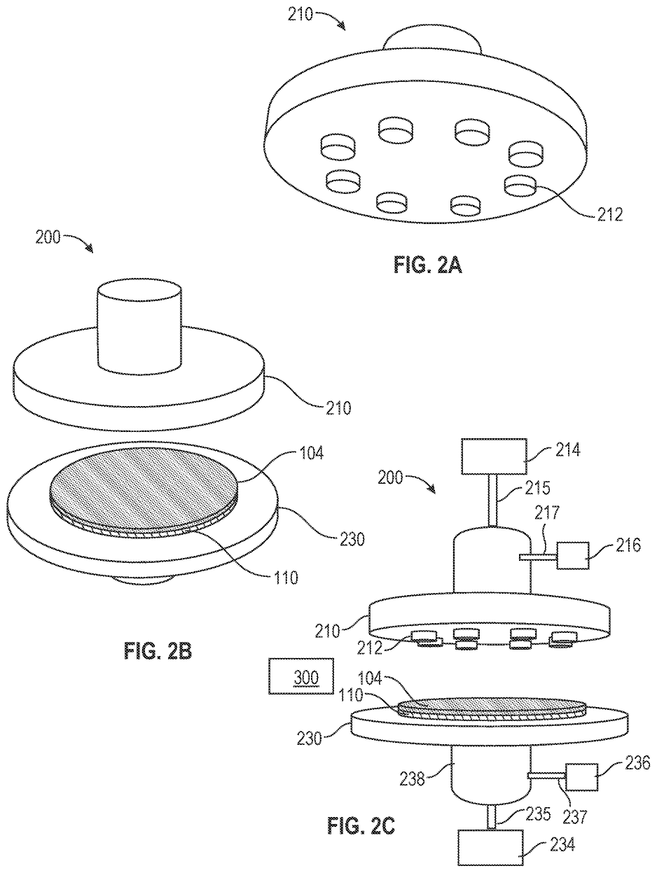

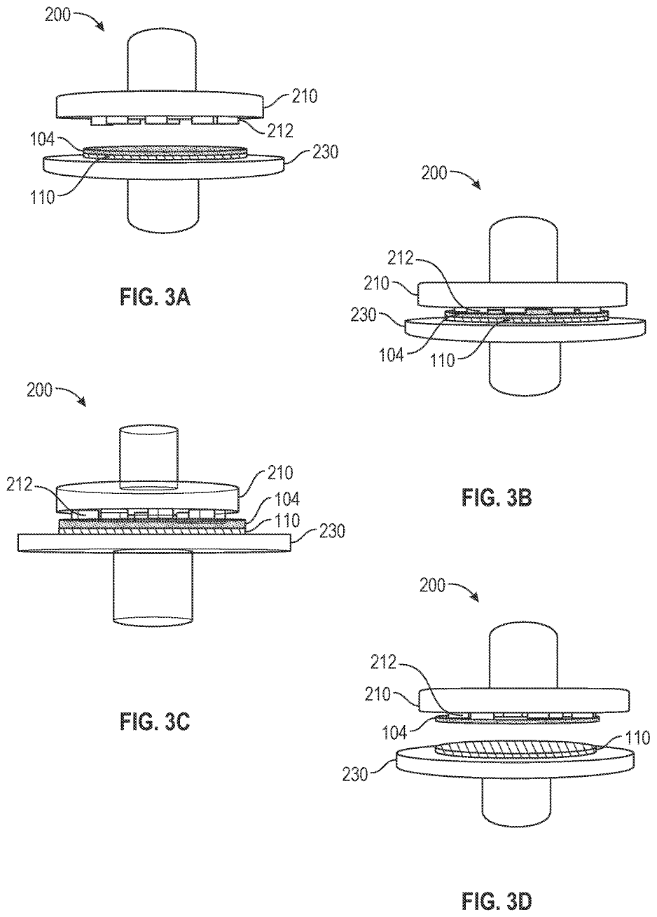

Accordingly, the methods and apparatus described herein can implemented at the die level (e.g., as shown in FIG. 1) or at the wafer level as shown in FIGS. 2A-2C and 3A-3D. According to one or more embodiments, after a laser lift-off process in which thermal decomposition aids in the separation of a sapphire substrate from a LED device, but the sapphire substrate has not been fully removed, a suction cup method and/or suction cup device and apparatus can be used to complete removal of the sapphire substrate from the LED device. In one or more embodiments, a suction cup method utilizes a customized tool described herein.

In one or more embodiments, after a laser lift-off process, a tape frame populated with LED devices undergoes ultraviolet cure, and then a pick and place (PnP) step is utilized to further process the LED devices to remove the sapphire substrate. Using a single LED device as an example, the LED device is picked from the ultraviolet cured tape frame and placed onto a carrier so that that sapphire substrate can be removed according to the apparatus and methods described herein.

Referring now to FIGS. 2A-2C, a first aspect of the disclosure pertains to a light emitting diode (LED) device sapphire substrate removal apparatus 200 comprising a holding stage 230 sized and shaped to receive and hold a carrier 110 of an LED device including a sapphire substrate 104. The sapphire substrate removal apparatus 200 further comprises a suction device 210 configured and positioned relative to the holding stage 230 to apply a suction force to the sapphire substrate 104 to remove the sapphire substrate 104 from the carrier 110.

In one or more embodiments (e.g., as shown in FIGS. 2B-2C), a surface of the holding stage 230 can be configured to receive and hold the carrier 110 such that a surface of the sapphire substrate 104 exposed. The suction device 210 is positioned and configured to apply a suction force to the exposed surface of the sapphire substrate 104. In particular, the suction device 210 is positioned opposite the holding stage 230 with the sapphire substrate 104 and the carrier 110 disposed on the holding stage 230 and in between the suction device 210 and the holding stage 230.

In one or more embodiments, the LED device sapphire substrate removal apparatus 200 further includes a suction system configured to apply suction to the carrier 110 when it is disposed on the holding stage 230. In particular, the suction system is configured to apply suction sufficient to hold the carrier 110 on the holding stage 230 while the suction device 210 applies a suction force to the sapphire substrate 104 to remove the sapphire substrate 104 from the carrier 110.

In one or more embodiments, at least one the holding stage 230 and the suction device 210 are movable in a vertical direction with respect to each other. In particular, the holding stage 230 and/or the suction device 210 can be moved vertically toward or away from the other (e.g., between positions shown in FIG. 3A, FIG. 3B, and FIG. 3D, and various other positions where the holding stage 230 and the suction device 210 are positioned closer to each other and further away from each other).

As shown in FIG. 2C, the LED device sapphire substrate removal apparatus 200 can further include a first motor 214 and a first shaft 215 configured to move the suction device 210 in a vertical direction relative to the holding stage 230. According to one or more embodiments, the LED device sapphire substrate removal apparatus 200 can also include a second motor 234 and a second shaft 235 configured to separately move the holding stage 230 in a vertical direction relative to the suction device 210. While not shown in the figures, one or more embodiments of the LED device sapphire substrate removal apparatus 200 can include only a second motor 234 and a second shaft 235 configured to move the holding stage 230 in a vertical direction relative to the suction device 210 (without a first motor 214 and a first shaft 215).

According to one or more embodiments, the suction device 210 comprises a plurality of first suction cups 212 disposed on a surface of the suction device 210 and configured and arranged to engage the sapphire substrate 104 and apply a suction force to the sapphire substrate 104 for removal from the carrier 110. The configuration and features of the plurality of suction cups 212 can be in accordance any conventional suction cups used to grip a surface, particularly conventional suction cups used together with a vacuum source. For example, according to one or more embodiments, a variety of materials suitable for use in adhering/providing suction to LED materials, particularly a sapphire substrate, can be used in fabricating the plurality of first suction cups 212. Some examples of suitable materials include rubber and plastic materials (e.g., natural rubber, silicone, nitrile butadiene rubber, polyurethane, and the like). In some embodiments, the holding stage 230 can also comprise a plurality of second suction cups (not shown) configured and arranged to apply suction to the carrier 110 when it is disposed on the holding stage 230. The plurality of second suction cups can be fabricated and provided in a configuration and arrangement similar to the plurality of first suction cups 212. While a particular number and arrangement of the plurality of first suction cups 212 is depicted in the figures, any number of suction cups 212 can be disposed in the suction device 210 in any variety of arrangements depending on the size and shape of the sapphire substrate being removed from an LED device. Further, while the suction cups 212 are depicted as having generally circular shapes, other shapes of suction cups and a combination of different shapes can also suitably be used.

According to one or more embodiments, the LED device sapphire substrate removal apparatus 200 further includes a first vacuum source 216 in fluid communication with the suction device 210. As shown, a first suction line 217 can connect the suction device 210 and the first vacuum source 216. The first suction line 217 can be in accordance with conventional vacuum suction connectors, for example, various hose or metal conduit connectors. In some embodiments, a second suction line (not shown) is provided that fluidly connects the first vacuum source 216 to the holding stage 230. In this embodiment, when a first vacuum source 216 is in fluid connection with both the holding stage 230 and the suction device 210, the first vacuum source 216 is configured to provide a holding force on the carrier 110 disposed on the holding stage 230 and a pulling force on the sapphire substrate 104 sufficient to remove the sapphire substrate 104 from the carrier 110 when the holding stage 230 and the suction device 210 are moved apart.

According to an alternative embodiment (e.g., as shown in FIG. 2C), in addition to a first vacuum source 216 in fluid communication with the suction device 210 via a first suction line 217, a second vacuum source 236 is provided in fluid communication with the holding stage 230 via a second suction line 237. In this embodiment, the first vacuum source 216 is configured to provide a pulling force on the sapphire substrate 214 sufficient to remove the sapphire substrate 104 from the carrier 110. The second vacuum source 236 is configured to provide a holding force on the carrier 110 sufficient to hold the carrier 110 on the holding stage 230 when the sapphire substrate 104 is removed from the carrier 110 when the holding stage 230 and the suction device 210 are moved apart.

In the embodiments shown, the holding stage 230 is mounted to a pedestal 238. The pedestal 238 can be configured to move the holding stage 230 in a vertical direction relative to the suction device 210.

As shown in FIG. 2C, according to one or more embodiments, the LED device sapphire substrate removal apparatus 200 further includes a controller 300 configured to control operation of one or more of the first vacuum source 216 and the second vacuum source 236 (if provided).

In one or more embodiments, the holding stage 230 is sized to hold a carrier having a dimension (e.g. a diameter, length, and/or width depending on the geometry of the carrier) in a range from about 1 millimeters to about 350 millimeters, for example about 75 millimeters to about 350 millimeters or about 75 millimeters to about 300 millimeters. In other embodiments, the dimension is in a range of about 1 millimeters to about 75 millimeters, for example about 1 millimeters to about 50 millimeters, about 1 millimeters to about 25 millimeters, about 2 millimeters to about 25 millimeters or about 3 millimeters to about 15 millimeters.

In one of more embodiments, where the sapphire substrate removal apparatus 200 comprises a controller 300 configured to control the first vacuum pump 216 and the second vacuum pump 236 (if provided), the controller 300 can further be configured to control vertical movement of the holding stage 230 and/or the suction device 210. The controller 300 generally includes a central processing unit (CPU), memory, and support circuits. The CPU may be one of any form of a general-purpose processor that can be used in an industrial setting. The memory, or non-transitory computer-readable medium, is accessible by the CPU and may be one or more of memory such as random-access memory (RAM), read only memory (ROM), floppy disk, hard disk, or any other form of digital storage, local or remote. The support circuits are coupled to the CPU and may comprise cache, clock circuits, input/output subsystems, power supplies, and the like. The various methods disclosed herein may generally be implemented under the control of the controller 300 by the CPU executing computer instruction code stored in the memory as, for example, a software routine. When the computer instruction code is executed by the CPU, the CPU controls the components of the sapphire substrate removal apparatus 200 to perform processes in accordance with the various methods. In one or more embodiments, some or all of the methods of the present disclosure are controlled hardware. As such, in some embodiments, the processes are implemented by software and executed using a computer system, in hardware as, e.g., an application specific integrated circuit or other type of hardware implementation, or as a combination of software and hardware.

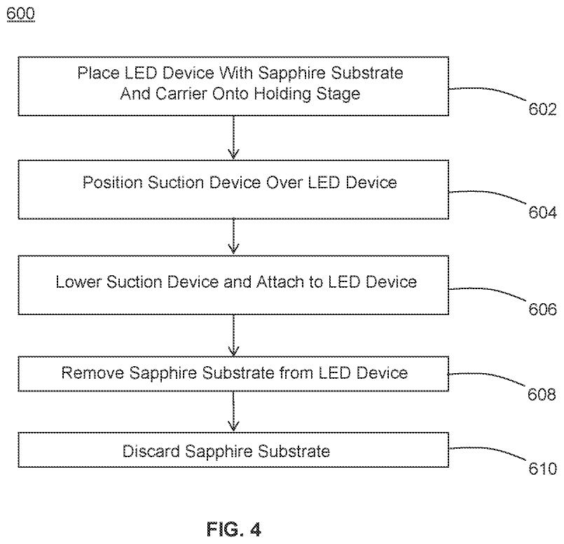

Referring now to FIG. 4, another aspect of the disclosure pertains to a method 600 of removing a sapphire substrate from an LED device. In one embodiment, the method 600 comprises placing the LED device comprising a sapphire substrate 104 and a carrier 110 onto a holding stage 230 (operation 602). The method can further comprise positioning the suction device 210 over the LED device (operation 604). Next, the suction device 210 is lowered to engage and attach to the LED device (operation 606). The sapphire substrate 104 is removed from the LED device using the suction device 210 (operation 608), and then the sapphire substrate 104 is discarded (operation 610).

In some embodiments, the method further comprises engaging and attaching the suction device 210 to the sapphire substrate 104, and separating the suction device 210 from the holding stage 230 to separate the sapphire substrate 104 from the carrier 110.

In some embodiments, the method comprises positioning the suction device 210 over the LED device by aligning the suction device 210 with the holding stage 230. For example, in embodiments wherein a plurality of first suction cups 212 are disposed on a surface of the suction device 210, the plurality of first suction cups 212 are aligned with the sapphire substrate 104 disposed on the holding stage 230 via the carrier 110.

In embodiments where the holding stage 230 and the suction device 210 are movable with respect to each other in a vertical direction, the method further comprises, in addition to lowering the suction device 210, raising the holding stage 230 until the suction device 210 engages the sapphire substrate 104. The method can further include pressing the suction device 210 and the sapphire substrate 104 together, particularly to form a seal between the plurality of first suction cups 212 and the sapphire substrate 104.

In one or more embodiments, the method includes applying vacuum suction to the holding stage 230 to apply a holding force to the carrier 110 and/or applying vacuum suction to the suction device 210 to apply a pulling force to sapphire substrate 104. According to one or more embodiments, the vacuum suction is applied to the plurality of first suction cups 212 disposed on the suction device 210 and in engagement with the sapphire substrate 104. In some embodiments, the vacuum suction is applied to the plurality of second suction cups (not shown) disposed on the holding stage 230 and in engagement with the carrier 110. In one or more embodiments, the holding force is greater than the pulling force. The method can further include moving one or more of the holding stage 230 and the suction device 210 apart in a vertical direction with respect to each other.

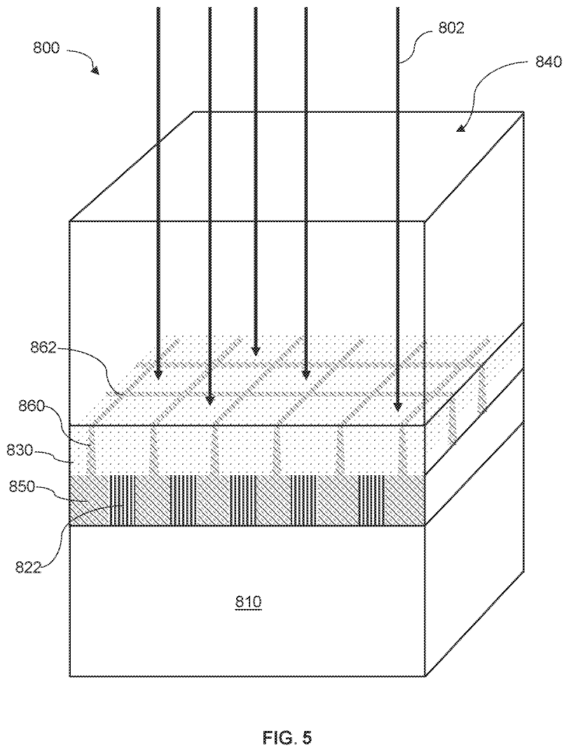

Embodiments of the disclosure can be utilized to remove a sapphire substrate 104 after a laser lift-off procedure from an LED die including a trenched metal grid. FIG. 5 illustrates in perspective view a structure 800 that allows for laser lift-off removal of a sapphire substrate 840 from contact with the LED die including a trenched metal grid 862. The structure 800 includes an LED die with semiconductor layers 830 (in which the uppermost layer is a GaN interface as described above) attached to a CMOS chip or wafer 810. Electrical and mechanical connection between the CMOS chip or wafer 810 and the semiconductor layers 830 is provided by electrically conductive pillars 822. The pillars define a cavity or gap that can be filled with an underfill material 850 to improve mechanical stability and attachment, and also improve electrical isolation.

In this embodiment, the semiconductor layers 830 include the trenched metal 860 that forms a trenched metal grid 862. In effect, trenches can help define a plurality of spaced mesas that, in turn, define pixels, with each of the plurality of spaced mesas comprising the semiconductor layers 830 and each of the spaced mesas having a height less than or equal to their width. The trenched metal 860, which is deposited in a space between each of the plurality of spaced mesas, provides optical isolation between each of the spaced mesas and allows electrical contact with sidewalls of the GaN LED. In one embodiment, electrical contact can include electrically contacting the n-type layer of each of the spaced mesas along sidewalls of the n-type layers. The space between each of the plurality of spaced mesas can result in a pixel pitch in a range of from about 1 μm to about 100 μm and space between adjacent edges of the p-contact layer of less than about 10% of the pixel pitch when the pixel pitch is in a range of from about 10 μm to about 100 μm, and when the pixel pitch is in a range of about 1 μm to about 10 μm, the space gap is less than or equal to about 5 μm and greater than about 0.5 μm.

In some embodiments, the trenched metal 860 comprises a reflective metal. In some embodiments, the trenched metal 860 width is less than or equal to about 4 μm and greater than about 0.5 μm, or less than or equal to about 3 μm and greater than about 0.5 μm. In some embodiments, the plurality of spaced mesas between the trenched metal grid 862 is arranged into pixels, and the pixel pitch ranges from about 5 μm to about 100 μm, or from about 30 μm to about 50 μm. In some embodiments, the semiconductor layers 830 have a thickness in a range of from about 2 μm to about 50 μm, for example from about 2 μm to about 30 μm, from about 2 μm to about 20 μm, or from about 2 μm to about 10 μm. In some embodiments, the thickness of the sapphire substrate 840 is in a range of from about 100 μm to about 800 μm.

Since the trenched metal 860 is attached between the sapphire substrate 840 and the semiconductor layers 830 of the LED die, sapphire lift-off requires breaking connection with the trenched metal 860. In this embodiment, laser light 802 decomposes the GaN (or other semiconductor layer 830 material) to create separation from the sapphire substrate 840. While the laser energy is not high enough to cause decomposition and direct release of the trenched metal 860, in regions where the area of semiconductor layer 830 material (e.g., GaN) is sufficiently greater than the area of the trenched metal 860, the force of nitrogen gas expansion from decomposition of semiconductor layer 830 material (e.g., GaN) causes separation of trenched metal 860 from the sapphire substrate 840. The apparatus and methods described herein can be used to remove the sapphire substrate 840 when the sapphire substrate remains adhered to the GaN interface (or other material) of the semiconductor layers 830 after laser lift-off, providing post laser lift-off processes and apparatus to complete removal of the sapphire substrate 840 from the LED die, solving a difficult and costly problem.

### EMBODIMENTS

Various embodiments are listed below. It will be understood that the embodiments listed below may be combined with all aspects and other embodiments in accordance with the scope of the disclosure, and the combination of embodiments is not limited to the combinations provided immediately below.

Embodiment 1 pertains to a light emitting diode (LED) device sapphire substrate removal apparatus comprising a holding stage sized and shaped to hold a carrier of an LED device including a sapphire substrate; and a suction device positioned to apply a suction force to the sapphire substrate to remove the sapphire substrate from the LED device.

Embodiment 2 pertains to the light emitting diode (LED) device sapphire substrate removal apparatus of embodiment 1, wherein the holding stage comprises a suction system configured to apply suction to the LED device sufficient to hold the LED device to the holding stage during a sapphire substrate removal operation.

Embodiment 3 pertains to the light emitting diode (LED) device sapphire substrate removal apparatus of embodiment 1 or 2, wherein the holding stage and the suction device are movable with respect to each other in a vertical direction.

Embodiment 4 pertains to the light emitting diode (LED) device sapphire substrate removal apparatus of embodiment 3, further comprising a first motor and a shaft configured to move the suction device in the vertical direction.

Embodiment 5 pertains to the light emitting diode (LED) device sapphire substrate removal apparatus of embodiment 3 or 4, further comprising a second motor and a second shaft configured to move the holding stage in the vertical direction.

Embodiment 6 pertains to the light emitting diode (LED) device sapphire substrate removal apparatus of any one of embodiments 1 to 5, wherein the suction device comprises a first plurality of suction cups.

Embodiment 7 pertains to the light emitting diode (LED) device sapphire substrate removal apparatus of any one of embodiments 1 to 6, wherein the holding stage comprises a second plurality of suction cups.

Embodiment 8 pertains to the light emitting diode (LED) device sapphire substrate removal apparatus of any one of embodiments 1 to 7, further comprising a first vacuum pump in fluid communication with at least one of the suction device and the holding stage.

Embodiment 9 pertains to the light emitting diode (LED) device sapphire substrate removal apparatus of embodiment 8, further comprising a first suction line connecting the suction device and the first vacuum pump.

Embodiment 10 pertains to the light emitting diode (LED) device sapphire substrate removal apparatus of embodiment 8 or 9, further comprising a second suction line connecting the holding stage and the first vacuum pump.

Embodiment 11 pertains to the light emitting diode (LED) device sapphire substrate removal apparatus of any one of embodiments 1 to 7, further comprising a second vacuum pump in fluid communication with the holding stage.

Embodiment 12 pertains to the light emitting diode (LED) device sapphire substrate removal apparatus of embodiment 11, further comprising a second suction line connecting the second vacuum pump and the holding stage.

Embodiment 13 pertains to the light emitting diode (LED) device sapphire substrate removal apparatus of embodiment 8, wherein the first vacuum pump is in fluid communication with the suction device and the holding stage, and the first vacuum pump is configured to provide a holding force on the carrier of the LED device and a pulling force on the sapphire substrate sufficient to remove the sapphire substrate from the LED device when the holding stage and the suction device are moved apart.

Embodiment 14 pertains to the light emitting diode (LED) device sapphire substrate removal apparatus of embodiment 11, wherein the second vacuum pump is configured to provide a holding force on the carrier of the LED device, and the first vacuum pump is configured to provide a pulling force on the sapphire substrate sufficient to remove the sapphire substrate from the LED device when the holding stage and the suction device are moved apart.

Embodiment 15 pertains to the light emitting diode (LED) device sapphire substrate removal apparatus of any one of embodiments 8 to 14 further comprising a controller configured to control operation of at least one of the first vacuum pump and the second vacuum pump.

Embodiment 16 pertains to the light emitting diode (LED) device sapphire substrate removal apparatus of any one of embodiments 1 to 15, wherein the holding stage is mounted to a pedestal configured to move the holding stage in a vertical direction.

Embodiment 17 pertains to a method of removing a sapphire substrate from an LED device, the method comprising: placing the LED device comprising the sapphire substrate and a carrier onto a holding stage, the holding stage sized and shaped to hold the carrier of the LED device; applying a suction device to the sapphire substrate; and separating the suction device and the holding stage to separate the sapphire substrate from the carrier, wherein after separation of the sapphire substrate from the carrier the carrier of the LED device is held on the holding device and the sapphire substrate is held on the suction device.

Embodiment 18 pertains to the method of embodiment 17, wherein the method further comprises prior to applying the suction device to the sapphire substrate, aligning the suction device with the holding stage such that the LED device is disposed therebetween

Embodiment 19 pertains to the method of any one of embodiments 17 to 18, wherein at least one of the holding stage and the suction device are movable with respect to each other in a vertical direction, and separating the suction device and the holding stage to separate the sapphire substrate from the carrier comprises moving at least one of the holding stage and the suction device vertically away from each other.

Embodiment 20 pertains to the method of any one of embodiments 17 to 19, wherein applying the suction device to the sapphire substrate comprises moving the suction device with respect to the holding device until the suction device contacts the sapphire substrate.

Embodiment 21 pertains to the method of any one of embodiments 17 to 20, wherein the method further comprises applying vacuum suction to at least one of (a) the holding stage to apply a holding force to the carrier of the LED device and (b) the suction device to apply a pulling force to the sapphire substrate.

Embodiment 22 pertains to the method of embodiment 21, wherein the holding force and the pulling force are sufficient to remove the sapphire substrate from the LED device as the holding stage and the suction device are moved apart.

Embodiment 23 pertains to the method of any one of embodiments 17 to 22, wherein the suction device comprises a plurality of suction cups.

Embodiment 24 pertains to the method of any one of embodiments 17 to 23, wherein the holding stage comprises a plurality of suction cups.

The use of the terms “a” and “an” and “the” and similar referents in the context of describing the materials and methods discussed herein (especially in the context of the following claims) are to be construed to cover both the singular and the plural, unless otherwise indicated herein or clearly contradicted by context. Recitation of ranges of values herein are merely intended to serve as a shorthand method of referring individually to each separate value falling within the range, unless otherwise indicated herein, and each separate value is incorporated into the specification as if it were individually recited herein. All methods described herein can be performed in any suitable order unless otherwise indicated herein or otherwise clearly contradicted by context. The use of any and all examples, or exemplary language (e.g., “such as”) provided herein, is intended merely to better illuminate the materials and methods and does not pose a limitation on the scope unless otherwise claimed. No language in the specification should be construed as indicating any non-claimed element as essential to the practice of the disclosed materials and methods.

Reference throughout this specification to the terms first, second, third, etc. may be used herein to describe various elements, and these elements should not be limited by these terms. These terms may be used to distinguish one element from another.

Reference throughout this specification to a layer, region, or substrate as being “on” or extending “onto” another element, means that it may be directly on or extend directly onto the other element or intervening elements may also be present. When an element is referred to as being “directly on” or extending “directly onto” another element, there may be no intervening elements present. Furthermore, when an element is referred to as being “connected” or “coupled” to another element, it may be directly connected or coupled to the other element and/or connected or coupled to the other element via one or more intervening elements. When an element is referred to as being “directly connected” or “directly coupled” to another element, there are no intervening elements present between the element and the other element. It will be understood that these terms are intended to encompass different orientations of the element in addition to any orientation depicted in the figures.

Relative terms such as “below,” “above,” “upper,”, “lower,” “horizontal” or “vertical” may be used herein to describe a relationship of one element, layer, or region to another element, layer, or region as illustrated in the figures. It will be understood that these terms are intended to encompass different orientations of the device in addition to the orientation depicted in the figures.

Reference throughout this specification to “one embodiment,” “certain embodiments,” “one or more embodiments” or “an embodiment” means that a particular feature, structure, material, or characteristic described in connection with the embodiment is included in at least one embodiment of the disclosure. Thus, the appearances of the phrases such as “in one or more embodiments,” “in certain embodiments,” “in one embodiment” or “in an embodiment” in various places throughout this specification are not necessarily referring to the same embodiment of the disclosure. Furthermore, the particular features, structures, materials, or characteristics may be combined in any suitable manner in one or more embodiments.

Although the disclosure herein has been described with reference to particular embodiments, it is to be understood that these embodiments are merely illustrative of the principles and applications of the present disclosure. It will be apparent to those skilled in the art that various modifications and variations can be made to the method and apparatus of the present disclosure without departing from the spirit and scope of the disclosure. Thus, it is intended that the present disclosure include modifications and variations that are within the scope of the appended claims and their equivalents. Therefore, it is understood the method and apparatus of the present disclosure is not to be limited to the specific embodiments disclosed, and that modifications and embodiments are intended to be included within the scope of the appended claims. It is also understood that other embodiments of the method and apparatus of the present disclosure may be practiced in the absence of an element/step not specifically disclosed herein.

1. A light emitting diode (LED) device sapphire substrate removal apparatus comprising:
a holding stage sized and shaped to hold a carrier of an LED device including a sapphire substrate; and
a suction device positioned to apply a suction force to the sapphire substrate to remove the sapphire substrate from the LED device.

2. The LED device sapphire substrate removal apparatus of claim 1, wherein the holding stage comprises a suction system configured to apply suction to the LED device sufficient to hold the LED device to the holding stage during a sapphire substrate removal operation.

3. The LED device sapphire substrate removal apparatus of claim 1, wherein the holding stage and the suction device are movable with respect to each other in a vertical direction.

4. The LED device sapphire substrate removal apparatus of claim 3, further comprising a first motor and a shaft configured to move the suction device in the vertical direction.

5. The LED device sapphire substrate removal apparatus of claim 4, further comprising a second motor and a second shaft configured to move the holding stage in the vertical direction.

6. The LED device sapphire substrate removal apparatus of claim 1, wherein the suction device comprises a first plurality of suction cups.

7. The LED device sapphire substrate removal apparatus of claim 6, wherein the holding stage comprises a second plurality of suction cups.

8. The LED device sapphire substrate removal apparatus of any one of claim 1, further comprising a first vacuum pump in fluid communication with at least one of the suction device and the holding stage.

9. The LED device sapphire substrate removal apparatus of claim 8, further comprising a second vacuum pump in fluid communication with the holding stage.

10. The LED device sapphire substrate removal apparatus of claim 8, wherein the first vacuum pump is in fluid communication with the suction device and the holding stage, and the first vacuum pump is configured to provide a holding force on the carrier of the LED device and a pulling force on the sapphire substrate sufficient to remove the sapphire substrate from the LED device when the holding stage and the suction device are moved apart.

11. The LED device sapphire substrate removal apparatus of claim 9, wherein the second vacuum pump is configured to provide a holding force on the carrier of the LED device, and the first vacuum pump is configured to provide a pulling force on the sapphire substrate sufficient to remove the sapphire substrate from the LED device when the holding stage and the suction device are moved apart.

12. The LED device sapphire substrate removal apparatus of claim 9, further comprising a controller configured to control operation of at least one of the first vacuum pump and the second vacuum pump.

13. The LED device sapphire substrate removal apparatus of claim 1, wherein the holding stage is mounted to a pedestal configured to move the holding stage in a vertical direction.

14. A method of removing a sapphire substrate from an LED device, the method comprising:
placing the LED device comprising the sapphire substrate and a carrier onto a holding stage, the holding stage sized and shaped to hold the carrier of the LED device;
applying a suction device to the sapphire substrate; and
separating the suction device and the holding stage to separate the sapphire substrate from the carrier, wherein after separation of the sapphire substrate from the carrier the carrier of the LED device is held on the holding device and the sapphire substrate is held on the suction device.

15. The method of claim 14, further comprising prior to applying the suction device to the sapphire substrate, aligning the suction device with the holding stage such that the LED device is disposed therebetween.

16. The method of claim 14, wherein at least one of the holding stage and the suction device are movable with respect to each other in a vertical direction, and separating the suction device and the holding stage to separate the sapphire substrate from the carrier comprises moving at least one of the holding stage and the suction device vertically away from each other.

17. The method of claim 14, wherein applying the suction device to the sapphire substrate comprises moving the suction device with respect to the holding device until the suction device contacts the sapphire substrate.

18. The method of claim 14, further comprising applying vacuum suction to at least one of (a) the holding stage to apply a holding force to the carrier of the LED device and (b) the suction device to apply a pulling force to the sapphire substrate.

19. The method of claim 18, wherein the holding force and the pulling force are sufficient to remove the sapphire substrate from the LED device as the holding stage and the suction device are moved apart.

20. The method of claim 14, wherein the suction device comprises a plurality of suction cups.
